(19) United States
(12) Patent Application Publication
(10) Pub. No.: US 2014/0113453 A1
(43) Pub. Date: Apr. 24, 2014

(54) TUNGSTEN CARBIDE COATED METAL COMPONENT OF A PLASMA REACTOR CHAMBER AND METHOD OF COATING

(71) Applicant: LAM RESEARCH CORPORATION, Fremont, CA (US)

(72) Inventors: Hong Shih, Walnut, CA (US); Lin Xu, Katy, TX (US); John Michael Kerns, Livermore, CA (US); Anthony Amadio, San Mateo, CA (US); Duane Outka, Fremont, CA (US); Yan Fang, Fremont, CA (US); Allan Ronne, Santa Clara, CA (US); Robert G. O'Neil, Fremont, CA (US); Rajinder Dhindsa, San Jose, CA (US); Travis Taylor, Fremont, CA (US)

(73) Assignee: Lam Research Corporation, Fremont, CA (US)

(21) Appl. No.: 13/659,328

(22) Filed: Oct. 24, 2012

(51) Int. Cl. H01L 21/3065; H01L 21/306; C23C 16/32; B32B 3/30; B32B 15/04; C23C 28/00

(52) U.S. Cl. 438/710; 428/627; 205/192; 427/249.18; 427/126.1; 427/123; 428/457; 428/612; 156/345.48; 257/E21.218

(57) ABSTRACT

A tungsten carbide coated chamber component of semiconductor processing equipment includes a metal surface, optional intermediate nickel coating, and outer tungsten carbide coating. The component is manufactured by optionally depositing a nickel coating on a metal surface of the component and depositing a tungsten carbide coating on the metal surface or nickel coating to form an outermost surface.

### FIELD OF THE INVENTION

The present invention relates generally to the fabrication of semiconductor wafers, and, more particularly, to high density plasma etching chambers having internal surfaces that reduce particle and metallic contamination during processing.

### BACKGROUND

In the field of semiconductor processing, vacuum processing chambers are generally used for etching and chemical vapor depositing (CVD) of materials on substrates by supplying an etching or deposition gas to the vacuum chamber and application of an RF field to the gas to energize the gas into a plasma state. Examples of parallel plate, transformer coupled plasma (TCP™) which is also called inductively coupled plasma (ICP), and electron-cyclotron resonance (ECR) reactors and components thereof are disclosed in commonly-assigned U.S. Pat. Nos. 4,340,462; 4,948,458; 5,200,232 and 5,820,723. Because of the corrosive nature of the plasma environment in such reactors and the requirement for minimizing particle and/or heavy metal contamination, it is highly desirable for the components of such equipment to exhibit high corrosion resistance.

During processing of semiconductor substrates, the substrates are typically held in place within the vacuum chamber by substrate holders such as mechanical clamps and electrostatic clamps (ESC). Examples of such clamping systems can be found in commonly-assigned U.S. Pat. Nos. 5,262,029 and 5,838,529. Process gas can be supplied to the chamber in various ways such as by a gas distribution plate. An example of a temperature controlled gas distribution plate for an inductively coupled plasma reactor and components thereof can be found in commonly-assigned U.S. Pat. No. 5,863,376. In addition to the plasma chamber equipment, other equipment used in processing semiconductor substrates include transport mechanisms, gas supply systems, liners, lift mechanisms, load locks, door mechanisms, robotic arms, fasteners, and the like. Various components of such equipment are subject to corrosive conditions associated with semiconductor processing. Further, in view of the high purity requirements for processing semiconductor substrates such as silicon wafers and dielectric materials such as the glass substrates used for flat panel displays, components having improved corrosion resistance are highly desirable in such environments.

As integrated circuit devices continue to shrink in both their physical size and their operating voltages, their associated manufacturing yields become more susceptible to particle and metallic impurity contamination. Consequently, fabricating integrated circuit devices having smaller physical sizes requires that the level of particulate and metal contamination be less than previously considered to be acceptable.

In view of the foregoing, there is a need for high density plasma processing chambers having internal, plasma exposed surfaces that are more resistant to erosion and assist in minimizing contamination (e.g., particles and metallic impurities) of the wafer surfaces being processed.

### SUMMARY

Disclosed herein is a process for coating a metal surface of a component of semiconductor processing equipment. The process comprises optionally depositing a nickel coating on a metal surface of the component of the semiconductor processing equipment and depositing a tungsten carbide coating on the nickel coating or on the metal surface to form an outermost surface.

Also disclosed herein is a component of semiconductor processing equipment. The component comprises a metal surface, an optional nickel coating on said metal surface, and a tungsten carbide coating on the metal surface wherein the tungsten carbide coating forms an outermost surface.

Further disclosed herein is a plasma processing chamber for a component of semiconductor processing equipment. The component comprises a metal surface, an optional nickel coating on said metal surface, and a tungsten carbide coating forming an outermost surface of the component, wherein the component is exposed to plasma during plasma processing of a semiconductor substrate in the chamber.

Also disclosed herein is a method of plasma etching a semiconductor substrate in a plasma processing chamber comprising a component having a metal surface, an optional nickel coating on said metal surface, and a tungsten carbide coating on the metal surface wherein the tungsten carbide coating forms an outermost surface of the component. The method comprises (1) supplying an etch gas to an interior of the chamber; (2) energizing the etch gas into a plasma; and (3) etching a semiconductor substrate with the plasma.

### BRIEF DESCRIPTION OF THE DRAWING FIGURES

FIG. 1 is a schematic cross-sectional view of a plasma reactor chamber having a metal component coated with a corrosion resistant tungsten carbide coating.

FIG. 2 illustrates a coated component cross section.

### DETAILED DESCRIPTION

Disclosed herein is a tungsten carbide coating of a metal component of a plasma processing reaction chamber. The tungsten carbide (“WC”) coating is preferably deposited by chemical vapor deposition (“CVD”) to provide an outermost dense pore-free CVD WC layer which may provide corrosion resistance to metal surfaces of components formed from stainless steel such as 316 and 300 series stainless steel alloys, aluminum, and aluminum alloys. Such components include bulk parts and component parts of linkage and actuator assemblies, gaskets such as an RF gasket, screws, gas and exhaust lines, RF return straps, manometer components, bellows, chamber walls, substrate supports, gas distribution systems including showerheads, baffles, rings, nozzles, fasteners (screws, washers, helicoils), heating elements, screens, liners, transport module components, such as robotic arms, inner and outer chamber walls, pin lifters, and the like.

Advantages of CVD WC coated components include enhanced lifetime of said component and enhanced wet cleaning compatibility. The WC coated component may exhibit increased physical toughness and zero porosity which may reduce or eliminate contamination from metals contained in the component. For example metal contaminants from stainless steel components such as chromium, nickel, iron, titanium, molybdenum, and the like may be reduced or eliminated with the use of the CVD WC coating. Chemical vapor deposition of the WC coating also forms pure, pore free, and fine grained structure in the WC coating.

The CVD WC coating also exhibits good thermal and electrical conductivity, and may exhibit plasma resistance under halogen etch gas chemistries such as fluorocarbon, fluorohydrocarbon, bromine, and chlorine plasmas, e.g., Cl₂ and BCl₃ plasma environments. The WC coating may react with F radicals to form WF₆, however WF₆ is volatile and may not be a contamination source for plasma processing reaction chambers. Additionally, the WC coating may be refurbished after the WC coating has been eroded under F radicals for a predetermined time period. CVD applications of the WC coating are preferred as the CVD processes may be used to coat components with complex geometry further reducing metal contamination from the components.

Components with complex geometry, such as a stainless steel spiral RF gasket, may receive conformal WC coatings through CVD processes. The RF gasket preferably has a low RF impedance and is also preferably electrically-conductive. The RF gasket is located near a region of plasma discharge and as such, active species such as F and 0 radicals, and ions may attack the RF gasket releasing metal contaminants to the processing region. Therefore, the WC coating may be used to reduce metal contaminants while maintaining the electrically-conductive properties of the RF gasket and also maintaining the preferred low RF impedance.

In describing the following embodiments, the term “component” includes any structure in a plasma processing apparatus which may be exposed to plasma, gases, vapors, and/or other reaction products. The component “surface” that is coated can be an exterior surface, or an interior surface that defines a hole, cavity, or aperture wherein the outermost coating on said exterior surface or said interior surface is the WC coating. The coating or coatings can be applied on one or more, or on all, exterior surfaces of the component. The coating or coatings can cover the entire exterior surface of component. The coating or coatings can also be applied on one or more, or on all, accessible interior surfaces of the component.

Although the tungsten carbide coating is applicable to any type of component having a metal surface, for ease of illustration, the coating will be described in more detail with reference to the apparatus described in commonly-assigned U.S. Published Application No. 2009/0200269 which is incorporated herein by reference in its entirety.

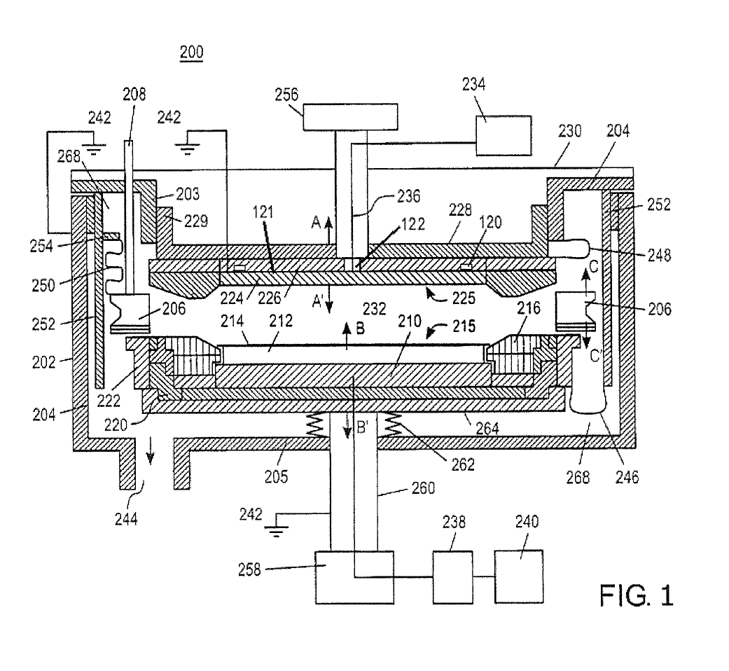

FIG. 1 shows an exemplary embodiment of an adjustable gap capacitively-coupled plasma (CCP) processing reaction chamber 200 (“chamber”) of a plasma processing apparatus. The chamber 200 comprises chamber housing 202; an upper electrode assembly 225 mounted to a ceiling 228 of the chamber housing 202; a lower electrode assembly 215 mounted to a floor 205 of the chamber housing 202, spaced apart from and substantially parallel to the lower surface of the upper electrode assembly 225; a confinement ring assembly 206 surrounding a gap 232 between the upper electrode assembly 225 and the lower electrode assembly 215; an upper chamber wall 204; and a chamber top 230 enclosing the top portion of the upper electrode assembly 225. The upper electrode assembly 225 comprises an upper showerhead electrode 224; and a gas distribution system such as one or more baffles 226 including gas passages for distributing process gas into the gap 232 defined between the upper showerhead electrode 224 and the lower electrode assembly 215. The upper electrode assembly 225 can include additional components such as RF gasket 120, a heating element 121, gas nozzle 122, and other components. The chamber housing 202 has a gate (not shown) through which a substrate 214, is unloaded/loaded into the chamber 200. For example, the substrate 214 can enter the chamber through a load lock as described in commonly-assigned U.S. Pat. No. 6,899,109, which is hereby incorporated by reference in its entirety.

In some exemplary embodiments, the upper electrode assembly 225 is adjustable in up and down directions (arrows A and A′ in FIG. 1) to adjust the gap 232 between the upper and lower electrode assemblies 225/215. An upper assembly lift actuator 256 can be used to raise or lower the upper electrode assembly 225. In the illustration, annular extension 229 extending vertically from the chamber ceiling 228 is adjustably positioned along cylindrical bore 203 of the upper chamber wall 204. A sealing arrangement (not shown) may be used to provide a vacuum seal between 229/203, while allowing the upper electrode assembly 225 to move relative to the upper chamber wall 204 and lower electrode assembly 215. A RF return strap 248 electrically couples the upper electrode assembly 225 and the upper chamber wall 204. The RF return strap 248 comprises an electrically-conductive and flexible stainless steel strap which may be WC coated accorded to embodiments described herein. The WC coating protects the metal strap from deterioration due to plasma radicals by preventing the metal strap from coming into contact with active species (radicals) generated by the plasma of process gas.

The RF return strap 248 provides a conductive return path between the upper electrode assembly 225 and the upper chamber wall 204 to allow the electrode assembly 225 to move vertically within the chamber 200. The strap includes two planar ends connected by a curved section. The curved section accommodates movement of the upper electrode assembly 225 relative to the upper chamber wall 204. Depending on factors such as the chamber size, a plurality (2, 4, 6, 8 or 10) RF return straps can be arranged at circumferentially spaced positions around the electrode assembly 225.

For brevity, only one gas line 236 connected to gas source 234 is shown in FIG. 1. Additional gas lines can be coupled to the upper electrode assembly 225, and the gas can be supplied through other portions of the upper chamber wall 204 and/or the chamber top 230.

In other exemplary embodiments, the lower electrode assembly 215 may move up and down (arrows B and B′ in FIG. 1) to adjust the gap 232, while the upper electrode assembly 225 may be stationary or movable. FIG. 1 illustrates a lower assembly lift actuator 258 connected to a shaft 260 extending through the floor (bottom wall) 205 of the chamber housing 202 to a lower conducting member 264 supporting the lower electrode assembly 215. According to the embodiment illustrated in FIG. 1, a bellows 262 forms part of a sealing arrangement to provide a vacuum seal between the shaft 260 and the floor 205 of the chamber housing 202, while allowing the lower electrode assembly 215 to move relative to the upper chamber wall 204 and upper electrode assembly 225 when the shaft 260 is raised and lowered by the lower assembly lift actuator 258. If desired, the lower electrode assembly 215 can be raised and lowered by other arrangements. For example, another embodiment of an adjustable gap capacitively coupled plasma processing chamber which raises and lowers the lower electrode assembly 215 by a cantilever beam is disclosed in commonly-assigned U.S. Published Application No. 2008/0171444, which is hereby incorporated by reference in its entirety.

If desired, the movable lower electrode assembly 215 can be grounded to a wall of the chamber by at least one lower RF strap 246 which electrically couples an outer conductor ring (ground ring) 222 to an electrically conductive part, such as a chamber wall liner 252 and provides a short RF return path for plasma, while allowing the lower electrode assembly 215 to move vertically within the chamber 200 such as during multistep plasma processing wherein the gap is set to different heights. An example of a coated RF strap is described in commonly-assigned U.S. Published Application No. 2009/0200269, which is hereby incorporated by reference in its entirety.

FIG. 1 further shows an embodiment of a confinement ring assembly 206 to confine a plasma volume proximate the substrate 214 and minimize surface areas with which the plasma interacts. In an embodiment, the confinement ring assembly 206 is connected to a lift actuator 208 such that the confinement ring assembly 206 is moveable in a vertical direction (arrows C-C′), meaning the confinement ring assembly 206 can be manually or automatically raised or lowered with respect to the upper and lower electrode assemblies 225/215 and the chamber 200. The confinement ring assembly is not particularly limited and details of suitable confinement ring assemblies 206 are described in commonly-assigned U.S. Pat. No. 6,019,060 and U.S. Published Application No. 2006/0027328, which are hereby incorporated by reference in their entireties.

The confinement ring assembly 206 can be grounded to a wall of the chamber by at least one RF strap 250 which electrically couples the confinement ring assembly 206 to an electrically conductive part such as upper chamber wall 204. FIG. 1 shows a conductive chamber wall liner 252 supporting a horizontal extension 254. The RF strap 250 may be WC coated and preferably comprises a plurality of WC coated metal straps which provide a short RF return path by electrically coupling the confinement ring assembly 206 to the upper chamber wall 204. The WC coated members 250 can provide conductive paths between the confinement ring assembly 206 and the upper chamber wall 204 at various vertical positions of the confinement ring assembly 206 within the chamber 200.

In the embodiment shown in FIG. 1, the lower conducting member 264 is electrically connected to an outer conductor ring (ground ring) 222 which surrounds dielectric coupling ring 220 which electrically insulates the outer conductor ring 222 from the lower electrode assembly 215. The lower electrode assembly 215 includes chuck 212, focus ring assembly 216, and a lower electrode 210. However, the lower electrode assembly 215 can include additional components, such as a lift pin mechanism for lifting the substrate, optical sensors, and a cooling mechanism for cooling the lower electrode assembly 215 attached to or forming portions of the lower electrode assembly 215. The chuck 212 clamps a substrate 214 in place on the top surface of the lower electrode assembly 215 during operation. The chuck 212 can be an electrostatic, vacuum, or mechanical chuck.

The lower electrode 210 is typically supplied with RF power from one or more RF power supplies 240 coupled to the lower electrode 210 through an impedance matching network 238. The RF power can be supplied at one or more frequencies of, for example, 2 MHz, 27 MHz and 60 MHz. The RF power excites the process gas to produce plasma in the gap 232. In some embodiments the upper showerhead electrode 224 and chamber housing 202 are electrically coupled to ground. In other embodiments the upper showerhead electrode 224 is insulated from the chamber housing 202 and supplied RF power from an RF supply through an impedance matching network.

The bottom of the upper chamber wall 204 is coupled to a vacuum pump unit 244 for exhausting gas from the chamber 200. Preferably, the confinement ring assembly 206 substantially terminates the electric fields formed within the gap 232 and prevents the electric fields from penetrating an outer chamber volume 268.

Process gas injected into the gap 232 is energized to produce plasma to process the substrate 214, passes through the confinement ring assembly 206, and into outer chamber volume 268 until exhausted by the vacuum pump unit 244. In a preferred embodiment, a screen 123 is located above vacuum pump unit 244 such that process gas evacuated therethrough may have particles or contaminants filtered from said process gas such as WF₆. Since reactor chamber parts in the outer chamber volume 268 can be exposed to reactive process gas (radicals, active species) during operation, they are preferably formed of material, such as stainless steel alloys, aluminum, or aluminum alloys with a CVD WC coating which can withstand the reactive process gas. Likewise, bellows 262 is preferably formed of a stainless steel having the WC coating.

In an embodiment where the RF power supply 240 supplies RF power to the lower electrode assembly 215 during operation, the RF power supply 240 delivers RF energy via shaft 260 to the lower electrode 210. The process gas in the gap 232 is electrically excited to produce plasma by the RF power delivered to the lower electrode 210.

In an embodiment, an electrically conductive member, such as an RF gasket 120 may be in direct contact with at least two adjacent chamber 200 electrically-conductive components. For example in a capacitively coupled plasma chamber the RF gasket may be mounted near the peripheral edge of a baffle 226 and an upper showerhead electrode 224 to improve RF conduction. Additionally, the conductive member, such as RF gasket 120 improves DC conduction between the two chamber components, preventing arcing between these two components. Preferably, the conductive member is flexible, such that the member can accommodate the contraction and expansion due to thermal cycling of the electrode assembly. Preferably the RF gasket 120 can be a spiral metallic gasket made of stainless steel or the like comprising an outermost coating of CVD WC.

In operation, a substrate 214 is positioned on a substrate support such as the lower electrode assembly 215 and is typically held in place by an electrostatic clamp 212 while He backcooling is employed. Process gas is then supplied to the plasma reactor chamber 200 by passing the process gas through baffle 226 and a gas distribution plate, such as the upper showerhead electrode 224. Suitable gas distribution plate arrangements (i.e., showerhead) arrangements are disclosed in commonly-assigned U.S. Pat. Nos. 5,824,605; 6,048,798; and 5,863,376, the disclosures of which are hereby incorporated by reference.

Chamber walls such as anodized or unanodized aluminum walls and metal components such as the substrate holder, fasteners, liners, gaskets such as RF gasket 120, stainless steel screws, stainless steel gas lines, stainless steel RF return straps, stainless steel manometer components, etc., that are exposed to plasma and show signs of corrosion may be coated with WC, thus avoiding the need to mask them during operation of the plasma chamber. Examples of metals and/or alloys that may be coated include stainless steel, anodized or unanodized aluminum and alloys thereof, refractory metals such as W and Mo and alloys thereof, copper and alloys thereof, etc., e.g., “SS 316”, “SS 304”, “AL-6061”, and “HAYNES 242”. In a preferred embodiment, the component to be coated is a stainless steel component. The coating may permit use of stainless steels without regard as to composition, grain structure, or surface conditions of the stainless steel alloy.

Exemplary embodiments of fasteners such as helicoils and screws which may comprise and outermost layer of WC are described in commonly-assigned U.S. Pat. No. 7,827,657 which is hereby incorporated by reference in its entirety. An exemplary embodiment of a lift pin assembly in a substrate support is described in commonly-assigned U.S. Pat. No. 7,995,323, which is hereby incorporated by reference in its entirety. Exemplary embodiments of manometer components are described in U.S. Pat. No. 6,901,808, which is hereby incorporated by reference in its entirety. Additionally, exemplary embodiments of a transport module component such as a robotic arm for transferring the substrate 214 to and from the chamber 200 are described in commonly-assigned U.S. Pat. No. 7,206,184, which is hereby incorporated by reference in its entirety.

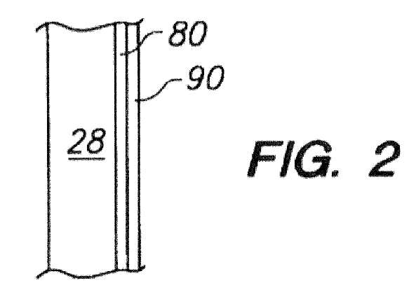

In the following discussion, an example of a component to be coated is a stainless steel chamber component such as RF gasket 120. The stainless steel chamber component 28 may have an optional nickel coating 80 and an outermost tungsten carbide coating 90, as illustrated in FIG. 2. The optional nickel coating 80 may increase adhesion between the stainless steel chamber component and the tungsten carbide coating 90. In an alternate embodiment, the stainless steel chamber component or other metal chamber component may only have the tungsten carbide coating 90, while not incorporating the intermediate nickel coating 80.

The WC coated stainless steel component may allow the stainless steel component to maintain electrical and thermal conductivity as well as the ability of the component to act as an RF conductor while reducing possible contamination from the materials comprised in the makeup of the stainless steel component. For example, stainless steel RF gasket 120 may maintain electrical and thermal conductivity, as well as low RF impedance, wherein the CVD WC coating forms an outermost layer.

The nickel (Ni) layer 80 may be coated on the stainless steel chamber component such as RF gasket 120 by any suitable technique, including for example plating such as electroless and electroplating, sputtering, immersion coating or chemical vapor deposition. The Ni layer can be pure Ni or a Ni alloy. Thus, the Ni layer can include at least 80% Ni and up to 20% other alloy elements. For example, the Ni layer can include at least 95 weight % Ni with up to 5 weight % other elements, more preferably at least 99 weight % Ni with up to 1 weight % other elements, and most preferably the Ni layer has a purity of at least 99.99%. Electroless plating is a preferred method of providing the Ni coating, allowing intricate interior surfaces such as those comprised in RF gasket 120 or other metal chamber components such as gas passages in gas supply components to be plated without the use of an electric current. More preferably the Ni coating is an electroplated coating. Other plating processes and coating techniques which can be used are disclosed in Coatings Technology: Fundamentals, Testing, and Processing Techniques (Arthur A. Tracton ed., 2006).

In order to ensure good adhesion of the plated material, the surface of the stainless steel chamber component, such as RF gasket 120, may preferably be thoroughly cleaned to remove surface material such as oxides or grease prior to plating. In an embodiment nickel alloy plating may include P in an amount of about 9 to about 12 weight percent.

The Ni coating 80 is sufficiently thick to adhere to the substrate and to further allow it to be processed prior to forming the WC coating 90 on the surface of the nickel. The Ni coating 80 can have any suitable thickness such as a thickness of at least about 5 micrometers, preferably from about 5 to 20 micrometers and more preferably about 8 and 12 micrometers.

After depositing the Ni coating 80 on the stainless steel chamber component, the plating can be blasted or roughened by any suitable technique. Or in a preferred embodiment, once the Ni is adhered to the stainless steel chamber component, the Ni surface can be treated to form pores in the Ni surface (e.g., using an acid solution to treat the Ni coating) such that it may be overcoated with the WC coating 90. In an embodiment, the WC coating may be applied without surface conditioning performed on the Ni coating 80.

The WC coating 90 is preferably applied by chemical vapor deposition (CVD) onto a roughened nickel coating 80. The thus roughened layer 80 may provide a particularly good bond with the CVD WC coating. As the WC coating 90 cools, it imparts a high mechanical compression strength to the Ni coating 80 and minimizes formation of fissures in the coating 90. The preferred coating method is via CVD. Preferably, the WC composition is Hardide-T™, Hardide-H™, or Hardide-M™ for the coating wherein the aforementioned compositions are available from Hardide Coatings Limited. An exemplary example of the CVD process for coating plasma chamber components with WC and exemplary WC compositions may be found in U.S. Pat. No. 8,043,692, which is incorporated by reference herein.

The WC coating 90 may be applied by other deposition techniques, including atomic layer deposition (ALD), plasma enhanced chemical vapor deposition (PECVD), and rapid thermal chemical vapor deposition (RTCVD).

The WC coating 90 in the preferred embodiment is deposited by chemical vapor deposition of WC preferably having a tungsten to carbon atomic ratio of 1:1 onto the Ni coating 80 to a suitable thickness such as in the range of about 25 to 75 micrometers, preferably 45 to 65 micrometers thick. If desired, the WC coating can be doped with fluorine (F) to strengthen and increase hardness of the WC coating. The thickness of the WC coating 90 can be selected to be compatible with the plasma environment to be encountered in the reactor (e.g., plasma etching, CVD, etc.). This layer of WC 90 may be coated on all or parts of the metal chamber components as discussed above. It is preferred that the WC coating be placed on the regions that are exposed to the plasma environment and/or corrosive gases used in the chamber such as parts in direct contact with the plasma or parts behind chamber components such as liners, etc., to prevent contamination of the semiconductor substrates processed in the reactor chamber by elements such as Fe, Cr, Ni, Ti, and Mo contained in underlying metal surfaces. In a further embodiment, the layer of WC 90 may form the outermost surface on a component, such as the RF gasket 120, wherein the component foams an electrical contact.

Preferably the WC coating is pore free. The WC coating preferably contains, by volume, less than about 0.5% porosity, such as less than about 0.1%, 0.05%, or less than 0.01%, i.e., has a density that approaches the theoretical density of the WC material. The WC coating preferably has no through porosity in at least 1 micron of thickness of the WC coating.

In a further embodiment, the exposed WC coated surfaces of the components within the chamber 200 may be polished to a desired, measurable RMS value sufficient to reduce or eliminate reactant adhesion thereto using various techniques to substantially remove pits, ridges, voids, and other surface roughness features from the surface to provide a homogenous surface. For instance, known electropolishing techniques may be used to polish at least some of the surfaces of the WC coated components of the chamber 200 to render them as smooth as possible. As known to those of ordinary skill in the art, electropolishing is accomplished by placing the metal in a chemical electrolyte bath and passing electrical current through the bath to remove metal ions from the surface of the metal to produce a smooth surface.

As an alternative to electropolishing, or in addition thereto, the WC coated component surfaces may be polished using physical (e.g., flame, plasma, electrodischarge or laser), chemical, mechanical, or other methods of polishing known to those of ordinary skill in the art. Laser polishing uses a short laser pulse to melt and resolidify a surface layer to produce a resultant smooth layer. Chemical polishing techniques polish a metal surface using controlled chemical reactions, as known to those of ordinary skill in the art. For example, phosphoric acid, nitric acid, fluoride solutions, or combinations thereof may be used to dissolve the high points on a metallic surface and produce a smooth surface. Mechanical polishing may be accomplished using an abrasive material on a polishing pad, an abrasive slurry, or a buffer element, or by using a grit-blasting device.

The various methods of polishing metals described herein may be combined. For instance, large surface areas may be polished with mechanical polishing methods while areas not accessible to mechanical polishing may be polished using other methods (i.e., electropolishing the interior of tubing).

Further disclosed herein is a method of plasma etching a semiconductor substrate in a plasma processing chamber comprising the WC coated component. The method comprises (1) supplying an etch gas to an interior of the chamber; (2) energizing the etch gas into a plasma; and (3) etching a semiconductor substrate with the plasma.

While embodiments of the coating have been described in detail with reference to specific embodiments thereof, it will be apparent to those skilled in the art that various changes and modifications can be made, and equivalents employed, without departing from the scope of the appended claims.

What is claimed is:

1. A process for coating a metal surface of a component of semiconductor processing equipment, the processing comprising:
optionally depositing a nickel coating on a metal surface of the component of semiconductor processing equipment;
depositing a tungsten carbide coating on said metal surface or on said nickel coating to form an outermost surface.

2. The process of claim 1, wherein the nickel coating is deposited by electroplating on the metal surface.

3. The process of claim 1, wherein the nickel coating is a nickel alloy.

4. The process of claim 1, wherein the tungsten carbide coating is deposited by chemical vapor deposition.

5. The process of claim 1, further including conditioning the metal surface of the component before depositing the optional nickel coating on said metal surface of the component or depositing the tungsten carbide coating on said metal surface of the component.

6. The process of claim 2, further including conditioning the deposited nickel coating on the metal surface of the component before depositing the tungsten carbide coating on the nickel coating.

7. The process of claim 1, wherein the component comprising the metal surface to be coated is an RF gasket, screw, gas line, RF return strap, manometer component, bellows, chamber wall, substrate support, gas distribution system, showerhead, baffle, ring, nozzle, fastener, heating element, screen, liner, transport module component, robotic arm, an actuator assembly, and/or helicoil.

8. The process of claim 1, wherein the component comprising the metal surface to be coated is a stainless steel spiral RF gasket.

9. The process of claim 1, wherein the outermost surface is a plasma exposed surface in a plasma etch chamber.

10. The process of claim 1, wherein the nickel coating is deposited to a thickness of 5-50 micrometers and the tungsten carbide coating is deposited to a thickness of 25-100 micrometers.

11. The process of claim 1, wherein the outermost surface is located on a portion of the component forming an electrical contact.

12. A component of semiconductor processing equipment comprising:
a metal surface;
an optional nickel coating on said metal surface; and
a tungsten carbide coating on said metal surface or nickel coating wherein said tungsten carbide coating forms an outermost surface.

13. The component according to claim 12, wherein then nickel coating has a thickness ranging from about 5 to about 50 micrometers and the tungsten carbide coating has a thickness ranging from about 25 to 100 micrometers.

14. The component according to claim 12, wherein then nickel coating has a thickness ranging from about 10 and 30 micrometers and the tungsten carbide coating has a thickness ranging from about 45 to 65 micrometers thick.

15. The component according to claim 12, wherein the nickel layer is present and comprises a Ni alloy or pure Ni.

16. The component according to claim 12, wherein the tungsten carbide layer is a CVD WC layer.

17. The component according to claim 12, wherein said component is an RF gasket, screw, gas line, RF strap, manometer component, bellows, chamber wall, substrate support, gas distribution system, showerhead, baffle, ring, nozzle, fastener, heating element, screen, liner, transport module component, robotic arm, an actuator assembly, and/or helicoil.

18. The component according to claim 12, wherein the metal surface of the component includes a roughened surface in contact with the nickel coating.

19. The component according to claim 12, wherein the nickel coating includes a roughened surface in contact with the tungsten carbide coating.

20. The component according to claim 12, wherein the component comprising the metal surface to be coated is a stainless steel spiral RF gasket.

21. The component according to claim 12, wherein the outermost surface of the component is a plasma exposed surface in a plasma etch chamber.

22. The component according to claim 12, wherein the outermost surface is located on a portion of the component forming an electrical contact.

23. A plasma processing chamber comprising the component according to claim 12, the component being exposed to plasma during plasma processing of a semiconductor substrate in the chamber.

24. A method of plasma etching a semiconductor substrate and the plasma processing chamber according to claim 23, comprising:
supplying an etch gas to an interior of the chamber;
energizing the etch gas into a plasma; and
etching a semiconductor substrate with the plasma.
